(19) United States
(12) Patent Application Publication
(10) Pub. No.: US 2005/0242341 A1
(43) Pub. Date: Nov. 3, 2005

(54) Apparatus and method for supporting a flexible substrate during processing

(76) Inventors: Christopher Todd Knudson, Santa Barbara, CA (US); Mark Jeffrey Sellars, Buellton, CA (US)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/961,125

(22) Filed: Oct. 8, 2004

Related U.S. Application Data
(60) Provisional application No. 60/509,829, filed on Oct. 9, 2003.
(60) Provisional application No. 60/509,886, filed on Oct. 9, 2003.
(60) Provisional application No. 60/509,890, filed on Oct. 9, 2003.

(51) Int. Cl. H01L 33/00; H01L 21/00

(52) U.S. Cl. 257/40; 438/26; 438/99; 257/99

(57) ABSTRACT

An preferred embodiment of an assembly for manufacturing an OLED display includes a flexible substrate, a frame having an inner perimeter defining a central opening, and at least one of an adhesive and a fastener securing the flexible substrate to the frame so that the flexible substrate spans the central opening. A preferred method for supporting a flexible substrate for an OLED display during manufacture of the OLED display includes providing a rigid frame having an inner perimeter defining a central opening, and securing the flexible substrate to the frame using at least one of an adhesive and a fastener so that the flexible substrate spans the central opening.

### CROSS REFERENCE TO RELATED APPLICATIONS

This application claims priority under 35 U.S.C. § 119(e) to U.S. provisional application Nos. 60/509,829; 60/509,886; and 60/509,890, each of which was filed on Oct. 9, 2003. The contents of each of these applications is incorporated by reference herein in its entirety.

### FIELD OF THE INVENTION

The present invention relates to the manufacture of electronic devices, such as organic light emitting diode (OLED) displays, that comprise a flexible substrate.

### BACKGROUND OF THE INVENTION

Flexible substrates used for electronic components generally require some type of support system during processing. One common support system uses a solid glass plate or substrate as a carrier for the flexible substrate. The flexible substrate is mounted on the carrier with an adhesive. Some of the problems associated with this type of support system are: (i) bubbling or air bubbles in the adhesive; (ii) solvents used for removal of the substrate during processing can damage the device (for example, solvents used for substrate removal after mushroom patterning can damage the mushroom); and (iii)) chemicals used during the processing can be trapped between the flexible substrate and the glass carrier. Other types of support systems include a clamping mechanism to hold the flexible substrate in place on the carrier. This type of arrangement can present difficulties, as the clamping mechanism cannot always hold the flexible substrate sufficiently taut.

The flexible substrate is usually mounted on the support carrier on a manual basis. The flexible substrate can be provided in a roll form. In this case, each sheet must be cut from the roll. The cut sheets are then transported to be mounted on the carrier. The flexible substrate potentially can be damaged during any of the cutting, storing, transporting, and mounting steps. Moreover, the aggregate time required to perform these steps can be substantial.

### SUMMARY OF THE INVENTION

The foregoing summary, as well as the following detailed description of a preferred embodiment, are better understood when read in conjunction with the appended diagrammatic drawings. For the purpose of illustrating the invention, the drawings show an embodiment that is presently preferred. The invention is not limited, however, to the specific instrumentalities disclosed in the drawings. In the drawings:

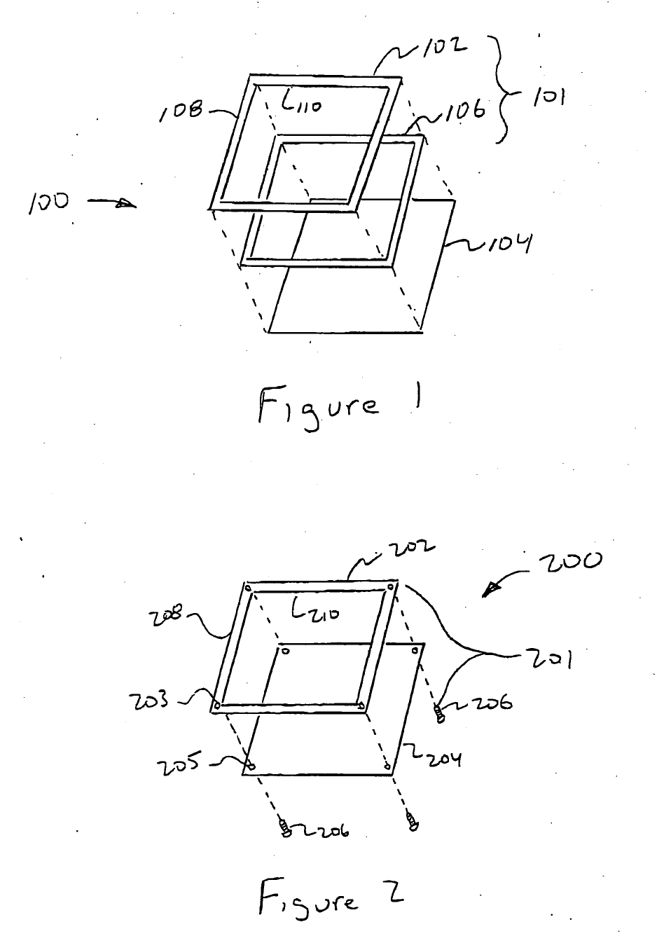

FIG. 1 is an exploded perspective view of a preferred embodiment of a flexible substrate process assembly;

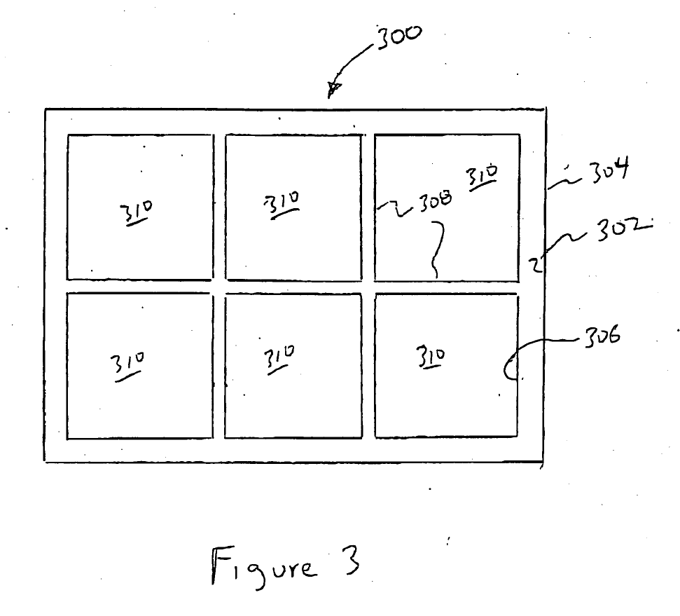

FIG. 2 is an exploded perspective view of another preferred embodiment of a flexible substrate process assembly;

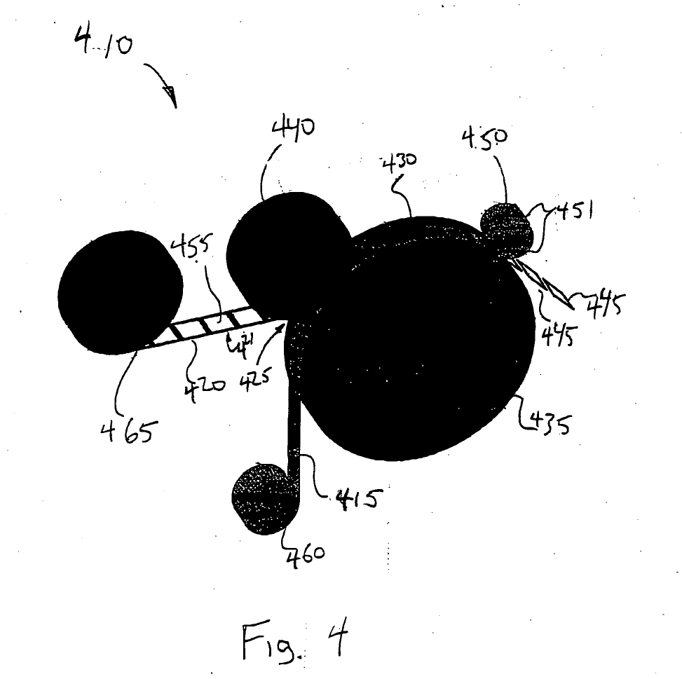

FIG. 3 is an plan view of another preferred embodiment of a flexible substrate process assembly;

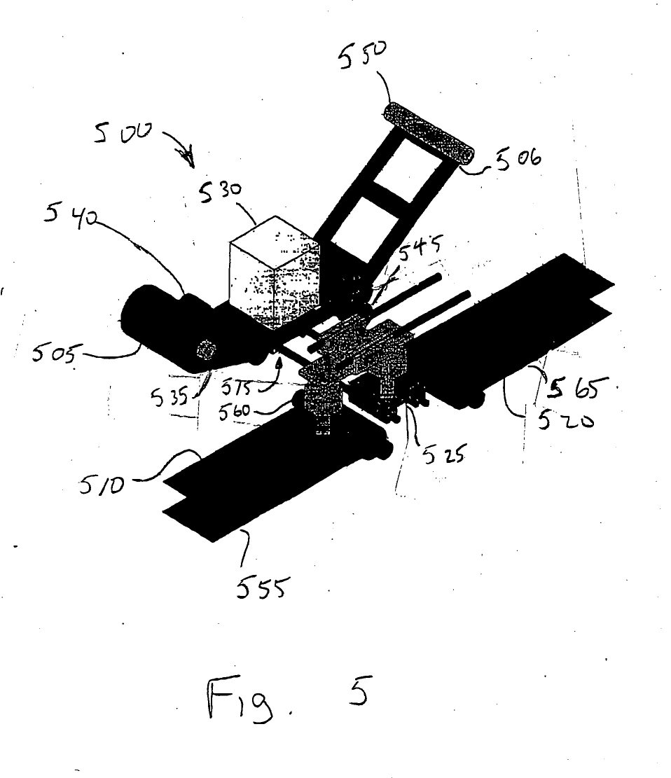

FIG. 4 is a perspective view of a preferred embodiment of an automated assembly device for assembling flexible substrates onto support frames; and

FIG. 5 is a perspective view of another preferred embodiment of an automated assembly device for assembling flexible substrates onto support frames.

### BRIEF DESCRIPTION OF THE DRAWINGS

A preferred embodiment of a substrate support system for supporting a flexible substrate during processing comprises a frame having a perimeter with one or more central openings made of a material compatible with the processing and a means for attaching the flexible substrate to the frame. In one embodiment, an adhesive is provided on the frame to hold a flexible substrate to the frame. In another embodiment, a plurality of fasteners are provided that are removably attachable to a plurality of fastener attachment holes provided in the frame to hold a flexible substrate to the frame.

A preferred embodiment of a substrate process assembly for use during processing of a flexible substrate includes a flexible substrate and a substrate support system.

A preferred method of assembling a substrate process assembly includes: providing a frame having a perimeter with one or more central openings; applying an adhesive to the frame; and attaching a flexible substrate to the frame with the adhesive.

Another preferred method of assembling a substrate process assembly includes: providing a frame having a perimeter with one or more central openings and a plurality of fastener attachment holes; positioning a flexible substrate proximate the frame spanning the central openings, the flexible substrate having through holes aligning with the plurality of fastener attachment holes in the frame; and attaching the flexible substrate to the frame with a plurality of fasteners that are removably attachable to the plurality of fastener attachment holes.

A preferred embodiment of a flexible substrate process assembly device for automated assembly of a flexible substrate from a continuous roll to a support frame from a continuous roll forming a substrate process assembly comprises: a rotating drum; and a backing roller adjacent the drum. The backing roller is capable of applying pressure toward the rotating drum.

Another preferred embodiment of a flexible substrate process assembly device for automated assembly of a flexible substrate from a continuous roll to a support frame from a continuous roll forming a substrate process assembly comprises: a rotating drum; a backing roller adjacent the drum, the backing roller being capable of applying pressure toward the rotating drum; a rotary cutter located near the rotating drum; a film unwind roller that is capable of dispensing a roll of flexible substrate; and a fame unwind roller that is capable of dispensing a roll of support frame.

Another preferred method of assembling a substrate process assembly comprises: providing a continuous roll of flexible substrate; loading the continuous roll of flexible substrate on a film unwind roller; providing a continuous roll of support frame; loading the continuous roll of support frame on a support frame unwind roller; and providing a flexible substrate process assembly device. The flexible substrate process assembly device includes a rotating drum and a backing roller. The preferred method also includes feeding the free end of the flexible substrate and the support frame between the rotating drum and backing roller; bonding the flexible substrate to the support carrier forming a substrate process assembly; and singulating the substrate process assembly with a cutter.

A preferred embodiment of a substrate process assembly device for automated assembly of a flexible substrate to a support frame forming a substrate process assembly comprises: a frame positioning shuttle capable of moving the support frame to an assembly area and removing the finished substrate process assembly from the assembly area; a way to position the flexible substrate near the support frame in the assembly area; and an applicator capable of applying pressure to the flexible substrate and the support frame in the assembly area.

Another preferred embodiment of a a substrate process assembly device for automated assembling of a flexible substrate to a support frame forming a substrate process assembly includes: a first conveyor capable of transporting the support frame; a second conveyor capable of transporting the substrate process assembly; a frame positioning shuttle capable of moving the support frame to an assembly area and removing the substrate process assembly from the assembly area; one or more loading/unloading shuttles capable of transferring the support frame from the first conveyor to the frame-positioning shuttle and transferring the substrate process assembly from the frame-positioning shuttle to the second conveyor; means to position the flexible substrate near the support frame in the assembly area; and an applicator capable of applying pressure to the flexible substrate and the support frame in the assembly area.

Another preferred method of assembling a substrate process assembly comprises: providing a substrate process assembly device having a frame positioning shuttle and an applicator; transporting a support frame on a first conveyor; transferring the support frame from the first conveyor to the frame-positioning shuttle; transporting the support frame on the frame-positioning shuttle to an assembly area; positioning a flexible substrate between the applicator and the support frame in the assembly area; applying pressure to the flexible substrate and the support frame in the assembly area; bonding the flexible substrate to the support frame to form a substrate process assembly; removing the substrate process assembly from the assembly area; transferring the substrate process assembly from the frame positioning shuttle to a second conveyor; and transporting the substrate process assembly on the second conveyor.

### DETAILED DESCRIPTION OF ILLUSTRATIVE EMBODIMENTS

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, “the”, “a” or “an” are employed to describe elements and components of the invention. This is done merely for convenience and to give a general sense of the invention. This description should be read to include one or at least one and the singular also includes the plural unless it is obvious that it is meant otherwise.

FIGS. 1-3 depict various embodiments of a frame for holding a flexible substrate during processing operations. Processing operations can include, for example, patterning, vapor deposition, liquid deposition, etc. Vapor deposition techniques can be used to apply organic layers by, for example, thermal evaporation, chemical vapor deposition, and the like. Alternatively, the organic layers can be applied by liquid deposition using suitable solvents. The liquid can be in the form of solutions, dispersions, suspensions, or emulsions. Liquid deposition techniques include, but are not limited to, continuous deposition techniques such as spin coating, gravure coating, curtain coating, dip coating, slot-die coating, spray-coating, and continuous nozzle coating; and discontinuous deposition techniques such as ink jet printing, gravure printing, and screen printing, any conventional coating or printing technique, including but not limited to spin-coating, dip-coating, roll-to-roll techniques, ink-jet printing, screen-printing, gravure printing and the like.

The frame can be formed from a material capable of withstanding the processing chemistries to which the flexible substrate is exposed during processing or manufacturing operations. In some embodiments, the frame can be made of non-magnetic materials, such as stainless steel (300 series) or composite, so that the frame can be used in equipment requiring non-magnetic materials, such as a sputtering tool having magnetron guns. The frame is capable of being cleaned so that the frame can be reclaimed or recycled, and reused. Solvents suitable for removing the flexible substrate from the frame after processing include, for example, acetone and isopropyl alcohol.

The support provided by the frame can be essential for spin coating a flexible substrate in a non-vacuum chuck during photoresist and polymer coat processing. Without the frame, the flexible substrate potentially could detach from the coater or, during wet chemistry processing, the flexible substrate may not stay in its designated slot in its associated cassette.

The flexible substrate, in general, is relatively thin, and can be made of any material suitable for use as a substrate. These materials can include, for example, plastic, metal, glass, and composite materials.

The frame can withstand processing chemistries when formed from an appropriate material, and can allow the flexible substrate to maintain its position during various patterning process steps. Moreover, the frame can eliminate any contact to a viewing side of the flexible substrate, which can promote cleanliness and eliminate scratches. The frame allows processing of the flexible substrate from incoming substrate cleaning through encapsulation, and the flexible substrate should not have to be removed from the frame until after display singulation. Moreover, the frame facilitates processing of both sides of the flexible substrate, and can provide access to both sides of the flexible substrate during critical manufacturing steps such as coating, cleaning, and inspection.

The flexible substrate described herein can be used to manufacture an electronic device. The term “electronic device” is intended to mean a device including one or more semiconductor layers or materials. Electronic devices include: (1) devices that convert electrical energy into radiation, e.g., a light-emitting diode, light-emitting diode display, or diode laser; (2) IR detectors, and devices that detect signals through electronic processes, such as photoconductive cells, photoresistors, photoswitches, phototransistors, and phototubes, and other types of photodetectors; (3) devices that convert radiation into electrical energy (e.g., a photovoltaic device or solar cell), (4) devices that include one or more electronic components that include one or more organic semi-conductor layers (e.g., a transistor or diode); and (5) organic electronic devices including OLED displays.

FIG. 1 is an exploded view of a preferred embodiment of a flexible substrate process assembly 100. The substrate process assembly includes a substrate support system 101 and a flexible substrate 104. The substrate support system 101 comprises a rigid or substantially rigid substrate frame 102 and an adhesive 106. The substrate support system 101 provides the flexible substrate 104 with a carrier and attachment mechanism to facilitate batch processing of the flexible substrate 104.

The materials from which the substrate support system 101 is formed should be selected so that the material does not act as a source of contamination during the any of the process steps performed on the flexible substrate 104 using the substrate support system 101.

The frame 102 has an outer perimeter 108, and an inner perimeter 110 that forms a central opening. The dimensions of the frame 102 should be chosen to be compatible with the machines used in processing the flexible substrate 104, such as standard semi-conductor or flat-panel display processing equipment. The use of a frame, such as the frame 102, that is compatible with standard processing equipment potentially can eliminate the need for costly custom tooling to process the flexible substrate 104.

The flexible substrate 104 can be made of common substrate materials, such as polyethylene terphthalate (PET), polyethylene naphthalate (PEN), polyarylate (PAR), polyesthersulphone (PES), polyimide (PI).

The flexible substrate 104 should remain taut on the frame 102 throughout the processing of the flexible substrate 104. For example, the film tension in the flexible substrate can be limited to approximately four percent strain to prevent ITO cracking.

The flexible substrate 104 is attached to the frame 102 using the adhesive 106. Adhesives suitable for use include, for example, thermal, UV-curable, and pressure sensitive adhesives. The adhesive 106 should be selected so as to be compatible with the materials used to process the flexible substrate 104, so that the adhesive can hold the flexible substrate 104 to the frame 102, without failing, as the flexible substrate 104 is processed. Compatible adhesives can be purchased, for example, from 3M (F9469PC, 9495MP), Tesa Tape, Inc. (tesa 4965) and Nitto Denko America, Inc. (5915, 5000NS).

The flexible substrate 104 can be removed from the frame 102 after multiple process steps have been performed on the flexible substrate 104. Solvents suitable for removing the flexible substrate 104 include, for example, acetone and isopropyl alcohol.

A potential advantage of using the adhesive 106 to hold the flexible substrate is that in some processes, the highest feature of the substrate/frame assembly 100 must be the flexible substrate 104. The use of an adhesive such as the adhesive 106 can prevent the substrate support system 101 form interfering with such process.

The adhesive 106 should be dispensed onto the frame in a uniform amount in relation to the width of the frame 102 and the desired thickness of the adhesive layer. The adhesive 106 can be applied a number of common ways, such as in a tape form. Alternatively, the adhesive 106 can be pre-formed into the correct shape as shown, for example, in FIG. 1.

Adhesive in the form of tape should be applied so that no overlap of the tape occurs, as such overlap can adversely affect the flatness of the substrate/frame assembly 100. Special assembly techniques may need to be followed when using adhesive, to prevent film buckling and warping. The frame 102 should have minimal distortion to facilitate lithographic patterning and robotic handling.

Automated machinery can be used to dispense the adhesive 106. The automated machinery should have the ability to start and stop at the desired locations on the frame 102 for the adhesive 106, to prevent overlapping at the corners of the frame 102 and to minimize waste and build-up. The flexible substrate 104 is then attached to the frame 102 in a taut manner. Optionally, the adhesive 106 can be applied to the flexible substrate 104 and then attached to the frame 102.

The frame 102 can be formed from metal, ceramic, glass, polymer or high performance polymers, such as DELRIN, TEFLON, stainless steel (for example stainless steel 304 and 316 Series), Titanium, ZYTEL, anodized aluminum and mixtures thereof, that may be reusable after processing. Care should be exercised in the selection of the material for the frame 102, as some plastic materials are not recommended for use for mounting substrates due to possible buckling and warping that can occur during processing.

The frame 102 allows the flexible substrate 104 to maintain its position during various patterning process steps. The frame 102 also eliminates any contact to a viewing side of the flexible substrate, which can promote cleanliness and eliminate scratches. The frame 102 should allow processing of the flexible substrate 104 from incoming substrate cleaning through encapsulation. The flexible substrate 104 should not have to be removed from the frame until after display singulation.

The frame 102 can be dimensioned to be compatible with the equipment used to process the flexible substrate 104. For example, some process equipment may accept an assembly approximately six inches square. Hence, the overall dimensions of the frame 102 should be approximately six inches square in this particular application.

The width of the frame 102, i.e., the distance between the outer perimeter 108 and the inner perimeter 110, can vary with the desired size of the central opening. For example, the frame 102 can have a width of approximately 0.25 inches in some applications.

The thickness of the frame 102 is significant, as increasing or decreasing the thickness can affect the rigidity of the frame 102. For example, the frame 102 can have a thickness of approximately 0.14 inches in some applications. To be compatible with some processing and manufacturing operations, the maximum thickness of frame/substrate assembly 100 should be less than approximately 0.50 inches, and preferably should be less than approximately 0.20 inches. For example, a substantially rigid flex frame of very thin metal or glass may be required for some types of processing or manufacturing operations. It should be noted that all of the preceding dimensions can vary to be compatible with the specified machines used in a particular application. The preceding dimensions are illustrative only, and are not intended to be limiting.

FIG. 2 is an exploded view of another preferred embodiment. FIG. 2 depicts a flexible substrate process assembly 200 that includes a substrate support system 201 and a flexible substrate 204. The substrate support system 201 comprises of a rigid or substantially rigid substrate frame 202 having a plurality of fastener attachment holes or perforations 203, and a plurality of attachment fasteners 206. The attachment fasteners 206 can be, for example, screws.

The substrate support system 201 provides the flexible substrate 204 with a carrier and attachment mechanism to facilitate batch processing. The material from which the substrate support system 201 is formed should be selected so that the material does not act as a source of contamination during the any of the process steps performed on the flexible substrate 204 using the substrate support system 201.

The frame 202 has an outer perimeter 208 and an inner perimeter 210 forming a central opening. The dimension of the frame 202 should be chosen to be compatible with the machines used in processing the flexible substrate 204, such as standard semi-conductor or flat panel display processing equipment. The use of a frame, such as the frame 202, that is compatible with standard processing equipment can eliminate the need for costly custom tooling to process the flexible substrate 104.

The fastener attachment holes 203 can removably receive the attachment fasteners 206. The fastener attachment holes 203 can be threaded, or can include nuts (not shown) for engaging the attachment fasteners 206. A plurality of through holes or perforations 205 are formed in the flexible substrate 204. The flexible substrate 204 is mounted on the frame 202 by inserting the attachment fasteners 206 through the through holes 205, and fixing the attachment fasteners 206 to the threads or nuts of the corresponding fastener attachment holes 203. Automated machinery can be used to form the through holes 205 in the flexible substrate 204, and to attach the flexible substrate 204 to the frame 205.

The attachment fasteners 206 should be made from a material that is compatible with the materials using to process the flexible substrate 204. For example, the attachment fasteners 206 can be formed from stainless steel or aluminum. The use of compatible materials can reduce the potential for contamination of the flexible substrate 204 during processing operations.

The flexible substrate 204 can be made of common substrate materials, such as polyethylene terphthalate (PET), polyethylene naphthalate (PEN), polyarylate (PAR), polyesthersulphone (PES), polyimide (PI)

The flexible substrate 204 should remain taut on the frame 202 throughout all of the process steps performed on the flexible substrate 204. For example, the film tension in the flexible substrate 204 can be limited to approximately four percent strain to prevent ITO cracking.

The frame 202 should have minimal distortion to facilitate lithographic patterning and robotic handling. The frame 202 also should be compatible with all process materials and steps. The frame 202 can be made from metal, polymer or high performance polymers, such as DELRIN, TEFLON, stainless steel (for example Stainless Steel 304 and 316 Series), Titanium, ZYTEL, anodized aluminum and mixtures thereof, that can be reused after processing of the flexible substrate 204. Care should be exercised in the selection of the material for the frame 102, as some plastic materials are not recommended for use for mounting substrates due to possible buckling and warping that can occur during processing.

The flexible substrate 204 can be removed from the frame 202 after multiple process steps have been performed on the flexible substrate 204. The frame 202 can then be cleaned and reused. The use of the attachment fasteners 206 can permit the frame 202 to be reclaimed or recycled for repeated use without the use of solvent.

The frame 202 can allow the flexible substrate 204 to maintain its position during various patterning process steps. The frame 202 also can eliminate any contact to a viewing side of the substrate, which can promotes cleanliness and eliminate scratches.

Care should be exercised when choosing and using the attachment fasteners 206. In particular, the attachment fasteners 206 can be the top most feature of flexible substrate process assembly 200 if the substrate support system 201 is not designed properly. In such a case, the use of the substrate support system 201 in some types of processing equipment could be limited or prohibited, or the attachment fasteners 206 could fall out during processing operations.

The frame 202 can be dimensioned to be compatible with the equipment used to process the flexible substrate 204. For example, some process equipment may accept an assembly approximately six inches square. Hence, the overall dimensions of the frame 202 should be approximately six inches square in this particular application.

The width of the frame 202, i.e., the distance between the outer perimeter 208 and the inner perimeter 210, can vary with the desired size of the central opening. For example, the frame 202 can have a width of approximately 0.25 inches in some applications.

The thickness of the frame 202 is significant, as increasing or decreasing the thickness can affect the rigidity of the frame 202. For example, the frame 202 can have a thickness of approximately 0.14 inches in some applications. To be compatible with some processing and manufacturing operations, the maximum thickness of frame/substrate assembly 200 should be less than approximately 0.50 inches, and preferably should be less than approximately 0.20 inches. For example, a substantially rigid flex frame of very thin metal or glass may be required for some types of processing or manufacturing operations. It should be noted that all of the preceding dimensions can vary to be compatible with the specified machines used in a particular application. The preceding dimensions are illustrative only, and are not intended to be limiting.

FIG. 3 shows another preferred embodiment in the form of a frame 300. As flexible substrates grow larger and larger, the support frame needed to support such flexible substrates can require additional support in the central opening so that the flexible substrates do not sag excessively. The frame 300 address this potential problem.

The frame 300 is substantially similar to the frames 102, 202, with the exception that the frame 300 has more central openings therein than the frames 102, 202. The frame 300 includes an outer portion 302 having an outer perimeter 304 and an inner perimeter 306.

One or more central supports 308 extend across the frame 300. The central supports 308 subdivide the frame 300 into two or more central openings 310. The frame 300 is depicted as having six of the central openings 310. This particular number of central openings 310 is depicted for exemplary purposes only. Alternative embodiments can having more or less than six the central openings 310 can be created by varying the number of the central supports 308. Also, the central openings 310 can be formed in different sizes and shapes by changing the locations of central supports 308. The location of the central supports 308 also can be dictated by the process parameters and equipment used to process the flexible substrate, so that the central supports 308 do not interfere with the processing of the flexible substrate.

Semi-automatic or completely automated devices can be used to assemble flexible substrates onto support frames, and to singulate the substrate and support frame into discrete assemblies. Such devices can provide economies of scale that lower production costs, and can reduce the potential for damage to the flexible substrate during assembly.

FIG. 4 depicts a preferred embodiment of an automated assembly device 410 for assembling flexible substrates onto support frames. The automated assembly device 410 can be used to: (i) assemble flexible substrates and support frames from continuous rolls of both components; (ii) bond the flexible substrate and support frame together on a drum by means of adhesive; and (iii) economically singulate (or cut) the completed assembly on the drum by means of a rotary cutter.

The automated assembly device 410 can be used to assemble a flexible substrate 415 to a support frame 420. As shown in FIG. 4, both the flexible substrate 415 and the support frame 420 are provided in a continuous roll form. The flexible substrate 415 and the support frame 420 are joined in an assembly area 425 to form a continuous substrate/frame assembly or substrate process assembly 430.

The flexible substrate 415 can be substantially similar to, for example, the flexible substrate 104 or the flexible substrate 204, with the exception that the flexible substrate 415 is supplied as a continuous roll.

The support frame 420 can be made of any suitable material that has the mechanical properties to support the flexible substrate 415 during processing. For example, the support frame 420 can be substantially similar to the support frame 102, the support frame 202, or the support frame 302, with the exception that the support frames 420 are attached together in a continuous form.

The flexible substrate 415 and the support frame 420 are threaded between a rotating drum or drum 435 and a backing roller 440 in the assembly area 425. The backing roller 440 and the drum 435 are dimensioned to accept and apply pressure to the flexible substrate 415 and the support frame 420. One or both of the drum 435 and the backing roller 440 are powered, to provide the requisite rotation thereto.

The substrate process assembly 430 is then singulated or cut into individual substrate process assemblies 445. In the depicted embodiment, a rotary cutter 450 is used to singulate (or cut) the continuous substrate process assembly 430. In another embodiment, the continuous substrate process assembly 430 can be rolled into a continuous roll form and transported to another area or machine prior to singulation. After singulation, each individual substrate process assembly 445 is ready for processing.

The support frame 420 should be of sufficient strength to support the flexible substrate 415 during processing. Each support frame 420 has one or more central openings 445. In the embodiment shown, the central openings 445 are formed in the support frame 420 before the support frame is formed into the continuous roll. Alternatively, the central opening 455 can be stamped in the support frame 420 as the continuous roll is unwound, and before the support frame 420 is joined with the flexible substrate 415. The stamping operation can be performed using a stamping machine (not shown) located between the frame unwind roller 465 and the assembly area 425. Alternatively, the stamping machine can be part of the backing roll 440.

The flexible substrate 415 can be supplied as a continuous roll disposed on a film unwind roller 460. The support frame 420 can be supplied as a continuous roll disposed on a frame unwind roller 465. The free ends of the continuous rolls are threaded between the drum 435 and the backing roll 440. Pressure is applied press the flexible substrate 415 and the support frame 420 together.

The support frame 420 can have a pressure sensitive adhesive 421 on a surface thereof. The flexible substrate 415 and the support frame 420 are pressed together, and are joined by the adhesive 421 to form the substrate process assembly 430. Alternatively, the flexible substrate 415 can be joined to the support frame 420 using ultrasonic energy. In this case, the support frame 420 can be made of plastic. An ultrasonic bonder (not shown) can be positioned in the assembly area 425. The ultrasonic bonder also can be part of one or both of the drum 435 and the backing roll 440.

The rotary cutter 450 includes a plurality of blades 451 that are designed to engage or mesh the drum 435 to cut the continuous substrate process assembly 430. In use, the completed continuous substrate process assembly 430 is threaded between the rotary cutter 450 and the drum 435. As the rotary cutter 450 rotates, the blades 451 cut the continuous substrate process assembly 430 to singulate the substrate process assembly 430 into individual substrate process assemblies 445.

FIG. 5 depicts another preferred embodiment of an automated assembly device in the form of an automated assembly device 500. The automated assembly device 500 can be used to assemble a flexible substrate 505 to a support frame 510, thereby forming a substrate/carrier assembly or substrate process assembly 520.

The automated assembly device 500 can: (i) convey the support frames 510 to an assembly area 515; (ii) economically singulate (or cut) flexible substrates 505 from a continuous roll material into cut sheets on an automated basis; (iii) pick-up and place each cut sheet of flexible substrate 505 onto a discrete support frame 510; (iv) apply pressure to the flexible substrate 505 and the support frame 510 to facilitate bonding thereof; and (v) convey the finished assemblies 520 away from the assembly area 515.

The flexible substrate 505 can be substantially similar to, for example, the flexible substrate 104 or the flexible substrate 204, with the exception that the flexible substrate 505 is supplied as a continuous roll.

The support frame 510 can be made of any suitable material having the mechanical properties to support the flexible substrate 505 during processing. For example, the support frame 510 can be substantially similar to the support frame 102, the support frame 202, or the support frame 302.

The flexible substrate 505 and the support frame 510 are joined in the assembly area 515 to form the substrate/carrier assembly or substrate process assembly 520. The support frame 510 is transported to the assembly area 515 by a frame-positioning shuttle 525. The frame-positioning shuttle 525 also can be used to support the support frame 510 during assembly.

An applicator/cutter 530 is provided to apply pressure to the flexible substrate 505 and the support frame 510, to facilitate assembly thereof. In the embodiment shown, the applicator/cutter 530 is located near the frame-positioning shuttle 525 in the assembly area 515, with the flexible substrate 505 and the support frame 510 positioned therebetween. The applicator/cutter 530 is capable of moving into and out of the assembly area 515. As the applicator/cutter 530 moves toward the frame-positioning shuttle 525, the applicator/cutter 530 can apply sufficient pressure to join the flexible substrate 505 to the support frame 510.

The flexible substrate 505 is supplied in a roll form, and can be stored on a film unwind roller 535. A free end 506 of the roll is threaded by a first roller 540, across the assembly area 515, through a pair of nip/pull rollers 545 to a selvage wind-up roller 550. The first roller 540 and the nip/pull rollers 545 position the flexible substrate 505 in the assembly area 515, between the applicator/cutter 530 and the frame-positioning shuttle 525.

The applicator/cutter 530 is located near the flexible substrate 505 in the assembly area 515. In one embodiment, the applicator/cutter 530 has a sharp edge formed along a perimeter thereof. As the applicator/cutter 530 moves toward the frame-positioning shuttle 525, the applicator/cutter 530 engages the flexible substrate 505 and cuts the flexible substrate 505 into a cut sheet. The flexible substrate 505, in the form of the cut sheet, is then applied to the support frame 510 to form the substrate process assembly 520.

In another embodiment, the applicator/cutter 530 has a central recess that is sized to accept the support frame 510. The applicator/cutter 530 applies the flexible substrate 505 onto the support frame 510 as the applicator/cutter 530 engages the frame-positioning shuttle 525. The perimeter of the central recess then cuts the flexible substrate 505 as the flexible substrate 505 is applied to the support frame 510 to form the substrate process assembly 520. The perimeter of the central recess also can provide tensioning of the flexible substrate 505 during assembly.

A first conveyor 555 transports the support frame 510 to a position proximate the frame-positioning shuttle 525. A frame loading/unloading shuttle 560 removes the support frame 510 from the first conveyor 555, and loads the support frame 510 onto the frame-positioning shuttle 525.

The frame-positioning shuttle 525 transports the support frame 510 to the assembly area 515. A second conveyor 565 is used to transport the substrate process assembly 520. Once the substrate process assembly 520 is completed, the frame-positioning shuttle 525 moves away from the assembly area 515, to a position proximate the second conveyor 565. The frame loading/unloading shuttle 560 removes the substrate process assembly 520 from the frame-positioning shuttle 525, and places the substrate process assembly 520 onto the second conveyor 565, The second conveyor 565 transports the substrate process assembly 520 away from the assembly area 515.

The flexible substrate 505 can be joined to the support frame 510 with an adhesive. The adhesive can be pre-applied to the support frame 510. Alternatively, an adhesive applicator (not shown) can be positioned along the first conveyer 555 to apply the adhesive to the support frame 510 while the support frame 510 is being transported along the first conveyer 555.

Alternatively, the flexible substrate 505 can be joined to the support frame 510 using ultrasonic energy. In this case, the support frame 510 is made of plastic and the flexible substrate 505 is joined to a frame portion of the support frame 510. An ultrasonic bonder (not shown) can be positioned near the assembly area 555. The ultrasonic bonder also can be part of one or both of the frame-positioning shuttle 525 and the applicator/cutter 530.

The foregoing description is provided for the purpose of explanation and is not to be construed as limiting the invention. While the invention has been described with reference to preferred embodiments or preferred methods, it is understood that the words which have been used herein are words of description and illustration, rather than words of limitation. Furthermore, although the invention has been described herein with reference to particular structure, methods, and embodiments, the invention is not intended to be limited to the particulars disclosed herein, as the invention extends to all structures, methods and uses that are within the scope of the appended claims. Those skilled in the relevant art, having the benefit of the teachings of this specification, may effect numerous modifications to the invention as described herein, and changes may be made without departing from the scope and spirit of the invention as defined by the appended claims.

1. A method for manufacturing an OLED display, the method comprising the steps of:
providing a flexible substrate;
providing a frame having an inner perimeter defining a central opening;
mounting the flexible substrate on the frame using at least one of an adhesive and a fastener; and
performing a processing operation on the flexible substrate.

2. The method of claim 1, wherein performing a processing operation on the flexible substrate comprises performing at least one of a patterning process, a vapor deposition process, and a liquid deposition process.

3. The method of claim 1, wherein mounting the flexible substrate on the frame using at least one of an adhesive and a fastener comprises mounting the flexible substrate on the frame so that the flexible substrate spans the central opening.

4. The method of claim 1, wherein mounting the flexible substrate on the frame using at least one of an adhesive and a fastener comprises mounting the flexible substrate on the frame so that the flexible substrate is substantially taut.

5. The method of claim 4, wherein mounting the flexible substrate on the frame so that the flexible substrate is substantially taut comprises mounting the flexible substrate on the frame so that a film tension of the flexible substrate is no greater than approximately four percent strain.

6. The method of claim 1, wherein mounting the flexible substrate on the frame using at least one of an adhesive and a fastener comprises mounting the flexible substrate on the frame using an adhesive compatible with materials used to perform the processing operation.

7. The method of claim 1, further comprising removing the flexible substrate from the frame, cleaning the frame, and mounting another of the flexible substrates on the frame.

8. The method of claim 1, wherein mounting the flexible substrate on the frame using at least one of an adhesive and a fastener comprises inserting the fastener through a hole formed in the frame, and a corresponding hole formed in the flexible substrate.

9. The method of claim 1, wherein providing a frame having an inner perimeter defining a central opening comprises providing a frame formed from a material that is compatible with materials used in the processing operation.

10. The method of claim 1, wherein providing a frame having an inner perimeter defining a central opening comprises providing a frame having a plurality of the central openings defined therein.

11. An OLED display manufactured in accordance with the method of claim 1.

12. A method for supporting a flexible substrate for an OLED display during manufacture of the OLED display, the method comprising the steps of:
providing a rigid frame having an inner perimeter defining a central opening; and
securing the flexible substrate to the frame using at least one of an adhesive and a fastener so that the flexible substrate spans the central opening.

13. An OLED display comprising a flexible substrate supported during manufacture in accordance with the method of claim 12.

14. An assembly for manufacturing an OLED display, comprising:
a flexible substrate;
a frame having an inner perimeter defining a central opening; and
at least one of an adhesive and a fastener securing the flexible substrate to the frame so that the flexible substrate spans the central opening.

15. The assembly of claim 14, wherein the flexible substrate is formed from at least one of polyethylene terpthalate; polyethylene napthalate; polyarylate; polyesthersulphone; and polyimide.

16. The assembly of claim 14, wherein the flexible substrate is substantially taut.

17. The assembly of claim 16, wherein a film tension of the flexible substrate is no greater than approximately four percent strain.

18. The assembly of claim 14, wherein the frame is substantially rigid.

19. The assembly of claim 14, wherein the frame is formed from at least one of a metallic material, a ceramic material, a glass material, and a polymeric material.

20. The assembly of claim 19, wherein the frame is formed from at least one of DELRIN; TEFLON; stainless steel; titanium, ZYTEL; and anodized aluminum.

21. The assembly of claim 14, wherein the fastener is disposed in a hole formed in the frame, and a corresponding hole formed in the flexible substrate.

22. The assembly of claim 21, further including at least one of a nut, and threads disposed in the hole formed in the frame for securing the fastener to the frame.

23. The assembly of claim 14, wherein the frame further includes a central support, and the frame has a plurality of the central openings defined at least in part by the central support.
